(19) United States
(12) Patent Application Publication
(10) Pub. No.: US 2017/0067961 A1
(43) Pub. Date: Mar. 9, 2017

(54) Method and Apparatus for Detection of Counterfeit, Defective or Damaged Devices

(71) Applicant: Colin Patrick O'Flynn, Halifax (CA)

(72) Inventor: Colin Patrick O'Flynn, Halifax (CA)

(73) Assignee: NEWAE TECHNOLOGY INC., Halifax (CA)

(21) Appl. No.: 14/846,065

(22) Filed: Sep. 4, 2015

(51) Int. Cl. G01R 31/317; G01R 31/30; G01R 31/3177

(52) U.S. Cl. CPC G01R 31/31703; G01R 31/3177; G01R 31/3004

(57) ABSTRACT

Methods and apparatus are provided for determining if an embedded system or integrated circuit is operating correctly, or if the device is faulty or counterfeit. Measurements of power consumption are used to determine the state of the device under test, these measurements being performed at multiple operating or environmental conditions to increase the ability of the apparatus to detect faulty and counterfeit devices.

### FIELD OF THE INVENTION

The present invention relates generally to detecting damage and modification to electronic devices, and, more particularly, a method and apparatus for determining if a digital embedded system (such as an integrated circuit) is defective, has been damaged, or has been replaced by a counterfeit device.

### BACKGROUND

As a device such as a digital circuit or device operates, it will consume varying amounts of power depending on the operation being performed and data being processed. Measuring the power consumption during operation leads to side-channel power analysis, which can be used for example to break cryptographic devices, as proposed by Kocher, P., Jaffe, J., and Jun, B. in “Differential power analysis” published in the proceedings of CRYPTO'99, 1999 on page 388.

Monitoring the power consumption can also be used to determine if a programmable device is executing the correct code. This could take the form of an apparatus designed to measure the power consumption of the target device during regular operation, and comparing the power signature of the device to some known reference, such as an known-good exemplar of a particular device design, as taught in published international patent application PCT/US2011/059244.

When reference is made herein to a device “having a particular device design” or “being of a particular device design” or similar phrases, what is meant is that the device is fabricated to be identical (within the bounds of manufacturing tolerance) to all other devices said to have that particular device design. Thus all correctly manufactured and properly working devices of a particular device design will be indistinguishable from one another for all practical purposes. One can think of the devices having a particular device design as being devices to which a manufacturer has given a particular model number and/or a particular part number. Thus, for example, all of the microprocessors manufactured by AMD having the model number K5-75, and to which AMD has assigned the part number AMD-K5-PR75ABR, are devices having one “particular device design.” All of the microprocessors manufactured by AMD having the model number K5-90, and to which AMD has assigned the part number AMD-K5-PR90ABQ, are devices having a different “particular device design.” Any specific instantiation of a device of a particular device design is referred to herein as an “exemplar” of that particular device design.

Rather than directly measuring the power consumption, it is also possible to measure the RF emissions of a device during operation. A signature of a device can be formed by measuring the regular radio frequency (RF) emissions of a known-good device; this signature could be defined for example by the amplitude of certain RF emissions in various frequency bands. This signature can then be compared to the emissions from another device, the device under test. This device under test could be a single device in a full system, or could be a device in a special test jig. A number of patents teach the use of RF or electromagnetic interference (EMI) emissions to characterize systems, such as U.S. Pat. No. 8,069,460; U.S. Pat. No. 8,825,823; and published U.S. patent application 2012/0226463.

In practice, performing this comparison is difficult when two devices are very similar. This problem arises when the “known-good” device is compared to a device which still functions but has been stressed such that it may fail prematurely; for example a device may have been removed from service, refurbished, and is now being sold as brand new. Simple comparisons will fail to effectively characterize an unknown device as refurbished.

Detection of defective, misrepresented, or counterfeit devices is of great importance when assembling an electronic system. Using a counterfeit device which does not meet the desired specifications could result in problems which are difficult to detect, such as a system which operates correctly under normal conditions, but when stressed will fail to operate correctly.

### SUMMARY

The present invention is directed to a method and apparatus to monitor the power consumption or other signatures of a device under test (DUT), while the DUT is performing a known task, operation or function. The DUT is configured to perform an operation that exercises many internal circuit or system blocks. If testing a microcontroller for example, a special test program is loaded into the microcontroller which exercises the internal memory, arithmetic logic unit, and peripherals. The recorded signature can be compared to a “known-good” signature to determine if the DUT is a counterfeit, damaged or defective exemplar of the original part for example.

This known task is referred to as the “signature operation”, and the specifics of this depend on the DUT. Examples of signature operations include but are not limited to executing at least one, i.e. one or more, instruction(s), performing one or more operation(s), and/or configuring one or more logic element(s). These may be combined for certain DUTs, for example when testing a field-programmable gate array (FPGA), it may be required to first configure the logic elements on the device, and then command the device to perform a certain task, operation or function, e.g. an operation on given input data such as an addition or multiply operation.

In accordance with an aspect of the invention, and in contradistinction to known methods and arrangements, the signature operation is carried out by the DUT under at least first and second environmental or operating conditions to generate respective first and second signatures. Signals or datasets respectively representing the first and second signatures are compared to signals or datasets respectively representing first and second reference signatures. The first reference signature is a reference signature of a known-good exemplar of the DUT's particular device design when performing the signature operation under the first environmental conditions. The second reference signature is a reference signature of the same or another known-good exemplar of the DUTâ\check{A}Źs particular device design when performing the signature operation under the second environmental condition. respectively. A signal designating the DUT as being potentially damaged, defective or counterfeit is generated in response to there being predetermined differences between at least one of a) the first signature and the first reference signature and b) the second signature and the second reference signature. I have recognized that this approach significantly improves the accuracy with which it can be determined if a device under test is damaged, counterfeit or defective because there may not be a significant difference between the signature of the DUT and the signature of a known-good device under a first environmental condition but yet there may be a significant difference between the signature of the DUT and the signature of the known-good device under the second environmental condition.

In particular embodiments, a signature may be recorded as a dataset comprising discrete samples of a continuous-time signature measurement, such as a power signature measurement. The rate at which samples are acquired should be sufficiently high to determine the operations being performed during individual clock cycles of the device under test (DUT). If the sample rate is too low, it becomes difficult or impossible to detect changes in the sampled signature for the purpose of detecting a counterfeit or damaged device. The sample rate thus must be high enough to make discernible small differences in the processing of data by the DUT.

The apparatus generating the sampled signature is not required to maintain linearity of the measurement, or otherwise maintain an absolute reference level. The signature needs only to be reproducible on the apparatus for a given DUT, rather than requiring the signature has appropriate units (such as measuring power in milli-Watts).

In an illustrative embodiment, the invention is implemented as a part of a piece of general-purpose test equipment, allowing a user to determine if a given part appears to be operating as the original manufacturer intended, but without having to develop an in-depth test plan which verifies every published specification. Deviation from the original manufacturer's specifications could be because of damage (such as electrical, mechanical, or thermal stresses during shipment), because the received part was not actually produced by the claimed manufacturer (i.e. is a counterfeit), or because the received part was actually a refurbished part.

Many devices are sold in different grades. For example a microprocessor might be sold in a version rated for an operating clock frequency of 8 MHz, and in a more expensive version rated for an operating clock frequency of 16 MHz. These parts are functionally identical, and might have simply been tested by the manufacturer to determine if the part should be rated at the higher or lower rating. Nefarious agents in the supply chain could misrepresent the device with an 8 MHz rating as being the 16 MHz version, as they can buy the lower-cost part and resell it as the higher-cost one. This will be referred to as “rebadging”.

In a case like this two devices may be functionally identical, and at room temperature the 8 MHz device might function at 16 MHz. Even using the “power signature” detection will fail, as the devices exhibit an extremely similar power signature.

To overcome this, embodiments of the invention perform the signature operation under various parameters, or “environmental conditions,” such as at various operating clock frequencies and supply voltages for the DUT. While other parameters can also be adjusted (such as operating temperature of the device), I have recognized that the most practical conditions to vary are the operating frequency and supply voltages. To avoid possible damage to the DUT, the varied environmental conditions can be kept within published specifications for the DUT.

If the DUT is capable of controlling its own clock frequency, such as many microcontrollers and microprocessors are, the external signals may not need to be modified. Instead the software being executed during the signature operation can first set the frequency to the required speed for the signature operation, and again run the signature operation at multiple speeds. Depending on the signature operation the external voltage can still be varied, but it may be sufficient to only perform the signature operation at several frequencies without adjusting voltage to detect a rebadged part.

Apparatus embodying the principles of the invention can be made an integral and permanent part of the DUT to detect failing parts or counterfeits without removing the DUT from the system in which it has already been integrated and of which it is a part. This would require an ability to load the DUT with the software to be executed during the signature operation, and performing this check at multiple operating frequencies and/or voltages. If the DUT is already capable of controlling its own operating frequency, this may be possible on “production” hardware since it does not require a separate programmable frequency generator.

Adjustments of operating clock frequency and operating voltage may cause timing violations in the circuits of devices. These timing violations can easily be detected, for example, in the power signature, thus simplifying the detection of devices which are for example (a) counterfeit, (b) rebadged versions of lower-rated parts, (c) have been stressed due to overheating during operation or removal from the PCB, and/or (d) damaged due to other electrical or mechanical stresses.

The invention can be used to test many different digital or other devices. For example measurements could be made of: a large microprocessor such as found in a desktop computer, a microcontroller for an embedded system, a digital module that plugs into a larger system, application specific integrated circuits (ASICs), field programmable gate arrays (FPGAs), Analog-to-Digital Converters (ADCs), and many other devices.

Examples of uses of this invention include detection of counterfeit integrated circuits (ICs), detection of counterfeit digital embedded circuits, validation of supply chains, and detecting faults or failures in digital embedded devices.

### BRIEF DESCRIPTION OF THE DRAWINGS

For a more complete understanding of the invention, reference is made to the following description and accompanying drawings, in which:

FIG. 1 shows testing apparatus embodying the principles of the invention.

FIG. 2A shows the power consumption of a device operating at a lower operating frequency.

FIG. 2B shows the power consumption of a device operating at a higher operating frequency.

FIG. 3A shows the power consumption of a device operating at a lower operating voltage.

FIG. 3B shows the power consumption of a device operating at a higher operating voltage.

FIG. 4A shows the power consumption in the frequency domain for a lower operating frequency.

FIG. 4B shows the power consumption in the frequency domain for a higher operating frequency.

FIG. 5 shows an embodiment of the testing apparatus designed as a stand-alone piece of test equipment.

FIG. 6 shows an embodiment of the testing apparatus designed as a computer-connected piece of test equipment.

FIG. 7 shows an embodiment of the testing apparatus designed to perform in-circuit testing, where a programmable oscillator changes the operating frequency.

FIG. 8 shows an embodiment of the testing apparatus designed to perform on-chip testing.

FIG. 9 show the use of the target devices own clock control circuitry to perform the signature operation at multiple operating frequencies.

FIG. 10 shows an embodiment of the testing apparatus designed to act as part of automated production equipment, allowing the testing of devices immediately before placing them on a circuit board.

FIG. 11 shows an example of the signature validation algorithm software which uses data from this apparatus.

### DETAILED DESCRIPTION OF ILLUSTRATIVE EMBODIMENTS

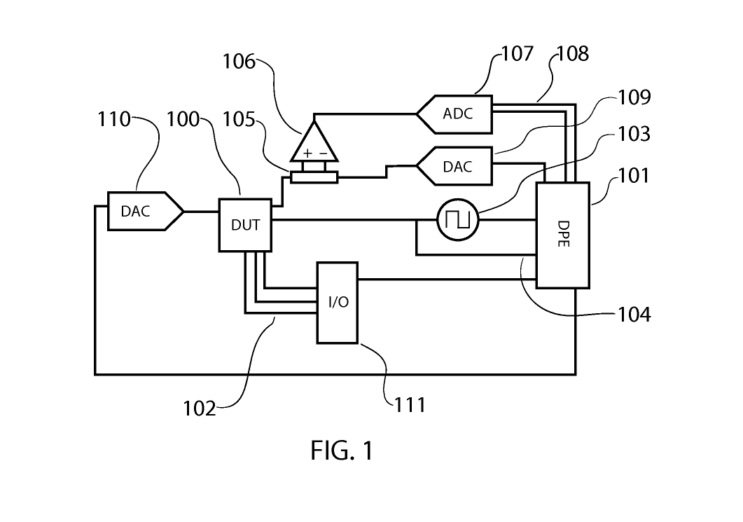

The disclosed illustrative testing apparatus is configured to be capable of measuring some indicator of the power consumption of a device under test, (DUT) while the DUT is performing a requested task. To this end the testing apparatus includes a digital processing engine which is responsible for commanding the DUT to perform some specific operation, while also recording the measurement used as the power consumption indicator. A diagram showing an embodiment of this apparatus is given in FIG. 1.

The digital processing engine operates under computer program control, and in particular, includes a computer-readable medium on which are stored program instructions that, when executed by one or more processors implement aspects of the invention.

In FIG. 1 the device under test (DUT) 100 is controlled by the digital processing engine (DPE) 101. A plurality of control lines 102 allow the digital processing engine 101 to command the DUT 100 via input/output (I/O) module 111 to perform actions such as downloading executable code, and/or requesting that certain operations are performed by the DUT. The digital processing engine 101 may directly control the DUT clock via a programmable oscillator 103, wherein the digital processing engine 101 configures the programmable oscillator 103 to operate at a specific frequency.

The output of the programmable oscillator 103 may be fed back to the digital processing engine 101 in order for the digital processing engine 101 to determine the location of clock transitions. This requires a clock feedback connection 104 for the digital processing engine 101 to monitor the clock generated by the programmable oscillator 103. This information can be used by the digital processing engine 101 to determine when to sample the power consumption of the DUT 100, as in devices operations will normally be performed only during the clock transitions. By knowing the location of clock transitions, the digital processing engine 101 can improve the alignment of power samples to operations in the DUT 100.

The programmable oscillator 103 may alternatively be part of the DUT 100, as for example when the DUT 100 already includes an ability to change operating frequencies. In this case the clock feedback connection 104 would come from the DUT 100.

In the embodiment in FIG. 1, a current measurement probe 105 is used to measure the currently flowing into the DUT 100. An example embodiment of the current measurement probe 105 is a resistor. If the current measurement probe 105 is a resistor, a voltage will be developed across the resistor which depends on the current flowing through said resistor. As the resistor is configured to be connected in series with the DUT 100 power supply, the current flowing through the resistor will be the same as the current drawn by the DUT 100 from the programmable power supply 109. The voltage across said resistor is thus related to the current consumed by DUT 100. There are many well-known alternative methods of measuring current consumption including use of a current transformer, Hall effect sensor, or electromagnetic probe. It will be appreciated by those skilled in the art that these and other probes are equivalent to the current measurement probe 105.

The measurement probe 105 does not require an absolute reference level for the current drawn by the DUT 100. Many of the well-known methods of measuring power consumption may provide only a measurement of that is a function of to the power consumption, but without an ability to determine the absolute power or current consumption. The measurement probe 105 is only required to provide a signal related to the power or current consumption of the DUT 100.

An example of a measurement probe 105 which provides a measurement that is a function of the current consumption of the DUT 100 would be a measurement probe detecting the magnetic-field emissions of the DUT 100. The magnetic-field emissions will have a relation to the current consumption that is able to discern if the DUT 100 is substantially different from some reference device, i.e. a known-good exemplar of the DUT's particular device design. The measurement of the magnetic-field emissions will not however directly provide information about the absolute current consumption of the DUT 100.

Signals representing samples of the power consumption of DUT 100 are developed using a combination of the current measurement probe 105, the analog processing circuitry 106, and the analog-to-digital converter (ADC) 107. The analog processing circuitry 106 in this embodiment takes the form of a differential amplifier which eliminates noise unrelated to the power measurement, while generating a suitable signal for the ADC 107. The digital processing engine 101 controls the sample time of the ADC 107 by use of a sample clock signal on lead 108.

The analog processing circuitry 106 may also include additional features to improve the signal-to-noise ratio at the input to the ADC 107 such as frequency-selective filtering or amplification. Such features are well known to those skilled in the art.

The ADC 107 and sample clock 108 are configured to sample the indicator of the power consumption with at a sufficiently high sample rate to determine the power consumption during each clock cycle of the DUT 100. This differentiates the configuration from apparatuses designed to determine the overall power consumption of the device for purpose of power-saving or monitoring. Such apparatuses do not require the high temporal precision of sample measurements, and typically measure the average power consumption only over the span of hundreds of thousands or more of clock cycles.

The sample clock 108 can run slightly slower than the DUT clock 103, and still provide sufficient temporal resolution. This will combine power measurements from several clock cycles into a single data point, but it is generally suggested the sample clock 108 run from 0.01 times (i.e. 1/100th the DUT clock 103) to 300 times the DUT clock 104. If the sampling operation which is controlled by the sample clock 108 does not provide high enough temporal resolution, this apparatus will be unable to reliably analyze a device to determine if it is counterfeit or defective.

The sample clock 108 must have a sufficient high frequency to discern differences in the power consumption signature of the DUT 100 compared to a reference device when the DUT 100 is substantially different from the reference device. Specific frequency requirements can be determined experimentally for a given DUT, type of DUT, or desired difference which must be detected.

The sample clock 108 may have a temporal relation to the DUT 100 clock, as determined by the clock feedback information connection 104. This could be accomplished by using the device clock feedback connection 104 to generate the sample clock 108 by way of a phase-locked loop or similar clock multiplication or division logic.

Maintaining a known or constant temporal relation between the clock feedback 104 and the ADC sample clock 108 improves the repeatability of the test procedure without requiring the ADC sample clock 108 to run at very high frequencies, that is, frequencies that are hundreds or thousands of times faster than the DUT operating frequency. Running the ADC sample clock 108 at very high frequencies increases the cost and power consumption of the overall apparatus.

The sequential samples from the ADC 107 will be received by the digital processing engine 101. Said samples may be recorded into datasets, the specific samples to include in the dataset being selected by the digital processing engine 101. Examples of the selection criteria for inclusion in one or more datasets include information about the current environmental conditions of the DUT 100, the operation being performed by the DUT 100, or the location of a trigger event from the DUT 100.

The digital processing engine 101 may also control the DUT 100 operating voltage using a programmable power supply or digital-to-analog converter (DAC) 109. The device might have multiple power supplies operating at different voltages, requiring additional programmable power supplies, represented by a second power supply 110 in FIG. 1 which, like power supply 109, is implemented as a DAC. The apparatus may have a plurality of programmable power supplies, and a given DUT may use one or more of these power supplies.

Comparing the power signatures of the DUT when operated at different power supply voltages and clock frequencies improves the detection of certain counterfeiting tactics. In particular a common problem is parts may be available in multiple grades: these grades reflect a part which is available in a high-speed and low-speed versions, where the high-speed version is more expensive. Under regular operating conditions the power signature of the high-speed and low-speed parts may not be easily distinguishable, allowing a counterfeiter to resell a low-speed version at the higher price commanded by the high-speed version.

The version of a particular reference device the comparison is performed against will vary depending on the required usage case for the apparatus. If it is required to detect what speed grade a part is, the reference dataset must be generated across only those devices of the specific speed grade. Another usage might require only the determination if a device has been damaged by ESD, and the reference dataset is built up using reference devices of all possible speed grades.

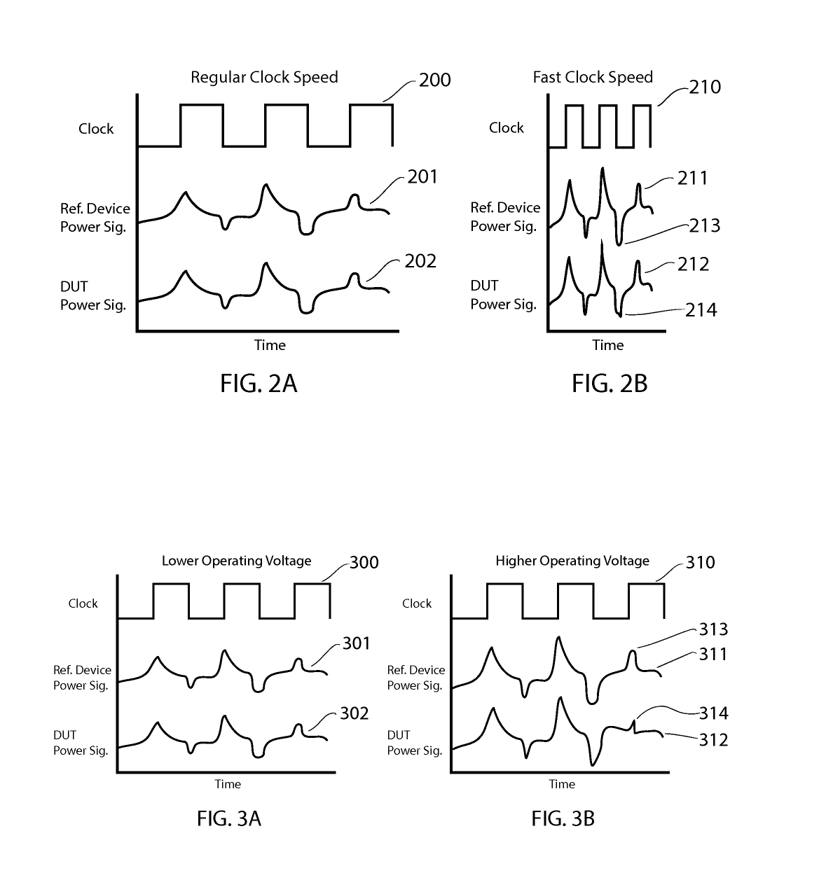

Examples of the power signatures recorded with this apparatus are shown in FIG. 2A and FIG. 2B. The power traces for two devices is recorded: a known-good “reference device” is shown in FIG. 2A, and the suspect device under test is shown in FIG. 2B. The clock of both devices is a certain frequency, denoted by the trace 200. The first version of the signature signal corresponding to the power measurement of the reference device performing the signature operation is shown in trace 201, and the second version of the signature signal corresponding to the power measurement of the DUT performing said signature operation is shown in trace 202. These traces appear very similar. When the operating frequency is increased, as in 210, the third version of the signature signal corresponding to the power measurement of the reference device during the signature operation shown in trace 211 becomes much easier to discern from the fourth signature signal corresponding to the power measurement of the DUT performing said signature operation at a higher frequency, which has a power trace shown in 212. Note in particular the differences between the shape of the peak at 213 in reference trace 211 and the shape of the corresponding peak at 214 in DUT trace 212.

Changes in the clock speed will naturally affect the recorded signature. Specifically, increasing the clock speed will increase the power consumption of the device. This can be seen by comparing the waveform 201 when the reference device is operating at a lower frequency to the waveform 211 when said reference device is operating at a higher frequency. The waveform 211 has higher peak-to-peak amplitude than waveform 201 due to the faster clock frequency. These waveforms are a graphical representation of a possible dataset recorded by the apparatus.

The “operating voltage” of a device is the supply voltage applied to the power input pin(s) of the device. Lowering the operating voltage the device is operating at will reduce timing margins, and increase the likelihood of timing errors being introduced. This fact can be used in combination with performing the signature operation at multiple frequencies to detect devices which appear to be operating differently from the original reference device. This failure to meet the original specifications may be because the DUT is a counterfeit part, or because the DUT has been damaged.

Rather than directly comparing a power signature to a reference waveform, it is also possible to compare the changes in the power signature for the DUT operating at least first and second, i.e., two or more, environmental conditions. Between FIG. 2A and FIG. 2B it can be seen that the reference device did not experience substantial changes in the waveform between the two operating frequencies, as moving from waveform 201 (at the lower frequency) to waveform 211 (at the higher frequency) only has some linear scaling due to the higher operating frequency. By comparison, the waveforms from the DUT can be seen changing in shape when waveform 202 (at the lower frequency) is compared to waveform 212 (at the higher frequency).

The test apparatus may generate a signal in response to the differences in these datasets. This signal indicates if the DUT is substantially different from the reference device, which suggests the DUT is counterfeit or defective.

FIG. 3A shows details of the power signature when operating a device at 1.8V operating voltage, which can be compared to the same signature operation being performed at a higher operating voltage in FIG. 3B. In this example the operating frequency is constant across both signature operations, as seen by the time-domain representation of the clock 300 and 310.

The difference between the two signature operations is a lower operating voltage of 1.8V for the first operation (FIG. 3A), and a higher voltage of 5.0V for the second operation (FIG. 3B). The first reference device power signature 301 is taken when the operating voltage is 1.8V, and the second reference device power signature 311 is taken when the operating voltage is 5.0V. Similarly, first DUT power signature 302 is taken when the operating voltage is 1.8V, and the second DUT power signature 312 is taken when the operating voltage is 5.0V. It can be noted the two signatures 301 and 302 are very similar, suggesting there is no problem with the DUT.

However, the DUT power signature 312 at 5.0V differs considerably from the reference signature 311 at the same voltage. For example section 313 of the reference signature 311 differs from the corresponding section 314 of the DUT signature 312.

What we see, then, is that using different operating voltages for the two signature operations has made it easier to detect that the DUT is a defective device in that, the difference(s) in the power signature at 5.0V were not present when performing the signature operation at 1.8V.

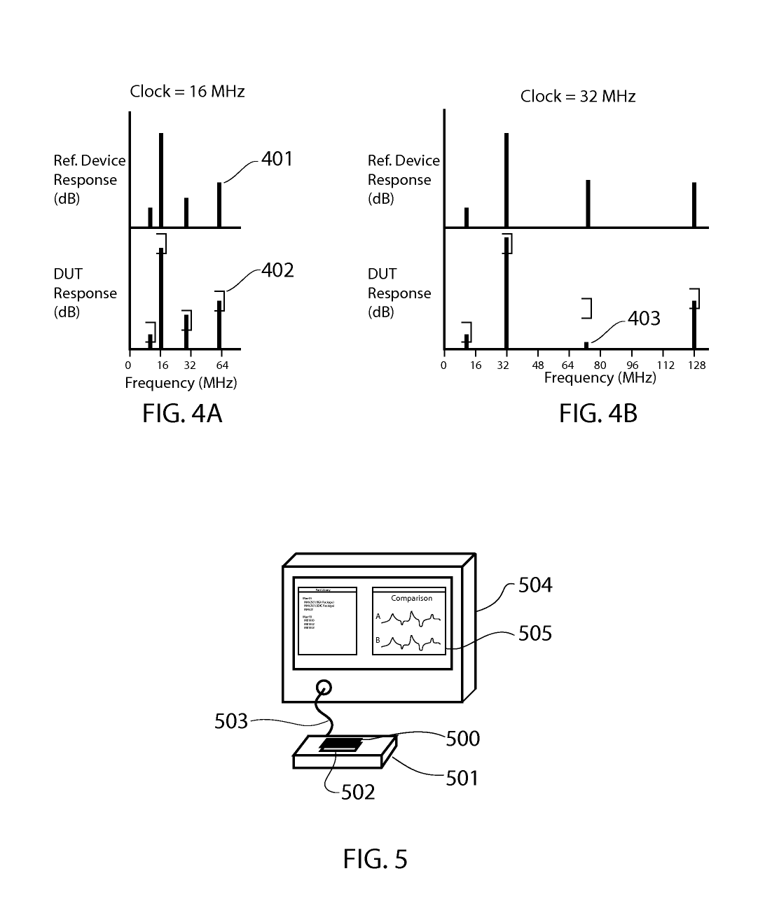

FIG. 4A and FIG. 4B show a measurement of the device signature in the frequency domain. FIG. 4A shows the reference device, and FIG. 4B shows the DUT. Both measurements are based on a power measurement taken while the devices are performing some known operation (the “signature operation”). The signature in the frequency domain can be represented in simplified form as the magnitudes of a plurality of spectral components 401. These can be compared to allowed ranges 402 which define an acceptable device. In this example the signature operation at 16 MHz results in substantially the same frequency spectrum between the reference device and the DUT, but results in a substantially different frequency spectrum between the reference device and the DUT at 32 MHz.

The frequency-domain signature can be simplified to define the expected magnitude of each spectral component as a function of the device frequency. When moving from 16 MHz to 32 MHz for example, it can be seen the frequencies of the main spectral components of the reference device are simply multiplied by two. This allows the test apparatus to clock the digital device from a wide range of frequencies without needing specific reference material for each possible test frequency.

Some frequency spectrum components may be caused by emissions from internal oscillators that do not vary with changing external frequency. The specifics will depend on the device under test, and a basic mapping of spectrum changes with varying main oscillator frequency can be easily determined.

In FIG. 4B, it is seen that spectral component 403 falls outside the allowed range at 32 MHz. This difference in spectral component may be the result of the fact that a particular section of the DUT might work acceptably at 16 MHz but fails at 32 MHz. The magnitude of the spectral component 403 would be used to signal there is a difference between the reference dataset and the dataset recorded from the DUT. Said signal could be used for a variety of purposes, for example by not limited to alerting the user of a piece of test equipment, logging the failure to internal memory, communicating with a networked device, or automatically causing the DUT to be rejected from a production environment.

A counterfeit device may use an entirely different internal architecture compared to a genuine device. For example a genuine device may be an Application Specific Integrated Circuit (ASIC), and the counterfeit device might be a general-purpose microcontroller which has been programmed to perform the same functions.

Such a counterfeit device will exhibit significantly different frequency emissions compared to the genuine device. While it might be possible to differentiate a genuine device from a counterfeit device using a single environmental condition (for example frequency emissions or operating voltage), using multiple environmental conditions improves the ability to differentiate a genuine device from a counterfeit device.

Different embodiments of the invention may be used depending on the specific usage case. What follows is a description of some example embodiments for use in three different scenarios: a production environment, in field-use, and in-circuit use.

FIG. 5 shows a possible embodiment of the test apparatus as a stand-alone test device. This embodiment could be used as part of an incoming acceptance test for example. The DUT 500 is inserted into the test box 501, by way of socket 502. The socket 502 allows the DUT 500 to be only temporarily connected to the test apparatus via test box 501.

The test box 501 connects to the main test system 504 via a test cable 503, which carries various signals to and from the DUT 500. These signals include the power measurement, voltage supplies, digital interface signals, and clock signal(s). The input/output module can be integrated into either the test box 501, or the main test system 504.

Variations of the test socket 502 can be designed as required by the DUT 500 to adapt to different physical packages, voltage requirements, or layout of the DUT 500. These various test sockets could be designed to be changeable such that a single test box 501 supports different variations of the socket 502, or different test boxes 501 could be used for each variation of the socket 502.

As in a typical piece of stand-alone test equipment, a user interface 505 is present which the operator uses to select various parameters and review the results. The operator for example can specify what type of device is being inserted into the test socket, which then loads appropriate signatures against which to compare the signature of the tested device. The digital processing engine is integrated into the test box 504.

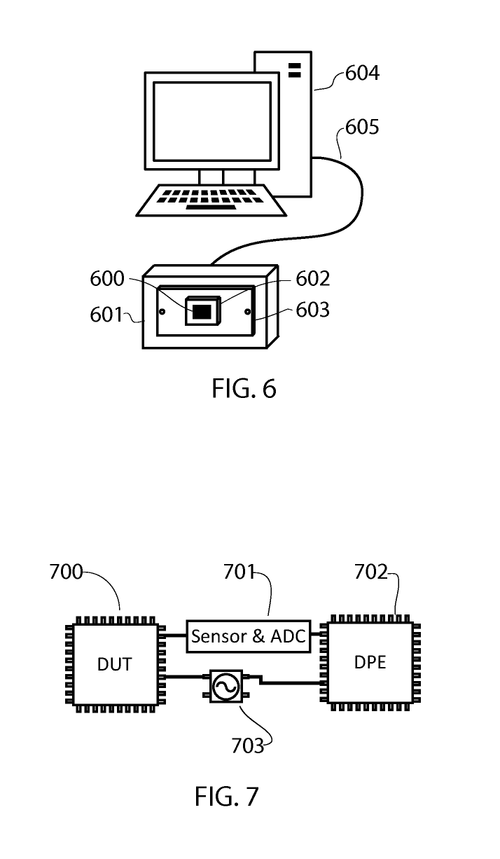

FIG. 6 shows a variation of the previous embodiment, where DUT 600 is tested with the test apparatus 601. This shows another possible embodiment of the invention, where the test socket 602 has been integrated into the main test apparatus 601. In this design the test socket 602 would be mounted on a carrier board 603, where the carrier board 603 can be easily removed from the main test apparatus 601.

This demonstrates one possible method of allowing various test sockets 602 to be easily connected to the test apparatus 601. Each test socket 602 can be specific for a component type or package being tested. Test socket 602 allows the temporary connection of the DUT 600 to the test apparatus 601, and can take many equivalent forms such as one or more test probes which temporary connect the DUT 600 to the test apparatus 601.

In this embodiment, the user interface 505 has been replaced with software running on a personal computer 604. This embodiment uses a connection 605 between the main test apparatus 601 and the personal computer 604, which could be for example USB or Ethernet connectivity. This embodiment reduces the size of the test apparatus 601, and is more suitable to either use in the field, or for integrating into a larger part of an automated test system.

A digital processing engine is still present in the main test apparatus 601, which at minimum performs functions such as controlling the ADC sampling clock and operating frequency of the DUT 600. The actual analysis and determination that a DUT is counterfeit or defective is performed on the personal computer 604, instead of being performed as part of the digital processing engine integrated into the test apparatus 601.

If using this apparatus as part of an automated test system, the personal computer 601 may be replaced by an industrial computer. In this case the results of the test are not displayed to a user, but used for further processing or automated binning of the DUT 600.

FIG. 7 shows an embodiment appropriate for in-circuit testing, where at least some part of the testing apparatus has been made an integral and permanent part of the device being tested. In this system the DUT 700 is for example an integrated circuit. The current measurement apparatus 701 encompasses the current measurement sensor, analog processing circuitry, and analog-to-digital converter (ADC). The samples from the ADC are processed by a digital processing engine 702, where said digital processing engine also controls the programmable oscillator 703 that is configured to clock the DUT 700. The I/O module is integrated into the digital processing engine 702 in this embodiment, but may be designed as a separate module instead. The specifics of the I/O module will depend on the DUT interface required.

There are many reasons that in-circuit testing may be desired instead of a stand-alone piece of equipment. For example by performing an in-circuit test, it is possible to validate the manufacture of integrated circuits on fully assembled devices.

The in-circuit test may also be used as part of a built-in-self-test (BIST) that the system performs. This test could be run at system startup, as requested by an operator, or automatically during regular system operation. Such a BIST is useful when attempting to determine if a particular device has been damaged; such damage could occur for example due to an electrostatic discharge (ESD) event.

The apparatus described herein requires that certain signature operations are performed by the DUT 700, during which power consumption, for example, is monitored and compared to a reference. Furthermore, these signature operations are performed at more than one environmental condition. With careful system design it is possible to perform such tests on a live system without disrupting regular operation.

This may require that the DUT 700 has some time during which it can perform the signature operation, such as an idle period when a processor is not handling requests. Alternatively, the signature operation could be chosen to represent some task the DUT 700 frequently performs, and thus the signature operation will naturally occur during processing.

Furthermore, the use of different environmental conditions (such as clock frequencies or operating voltages) may occur during regular operation of DUT 700. The DUT 700 may perform clock frequency scaling or adjust its operating voltage based on system load. In this case the digital processing engine 702 can look for a suitable combination of environmental conditions and DUT 700 operation during which the DUT 700 should generate a known signature.

The current measurement apparatus 701, digital processing engine 702, and programmable oscillator 703 may be located on a physically separate location from the DUT 700. The connection to the DUT 700 is made with temporary probes, instead of being permanently integrated into the system.

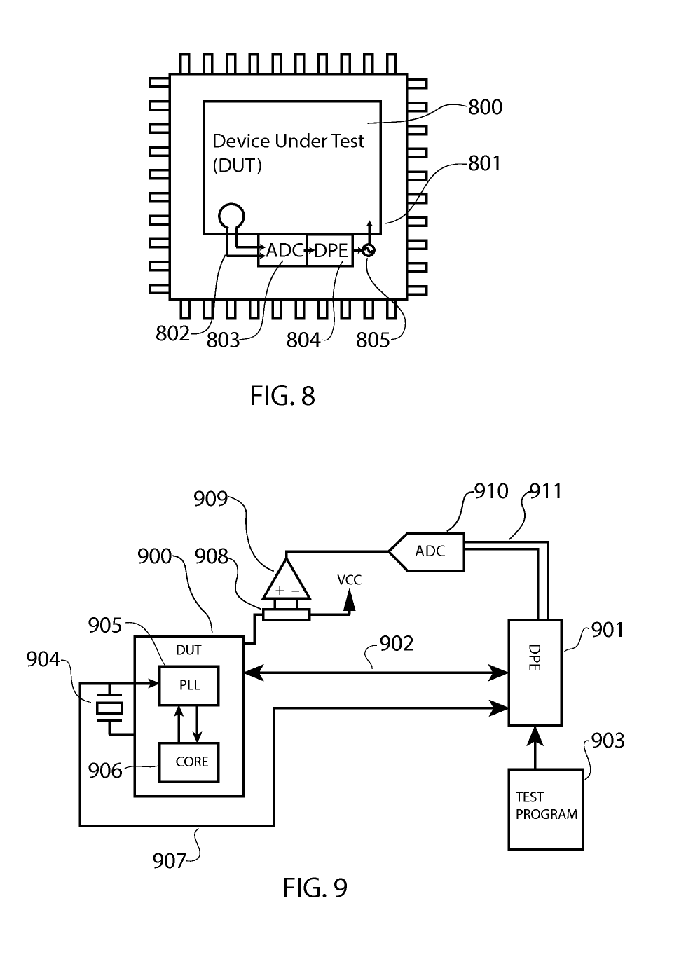

In-circuit testing can be further expanded to a test apparatus on a single integrated circuit which performs a self-test, as shown in FIG. 8. Here the DUT 800 is the main portion of integrated circuit die 801. Again current measurement 802 is used which encompasses a suitable current measurement sensor, such as a small loop antenna along with analog processing circuitry, which is fed into the analog-to-digital converter 803. The output of the analog-to-digital converter 803 is fed into the digital processing engine (DPE) 804.

The digital processing engine 804 controls a clock generator 805, which feeds the DUT 800. It may be desired to move some of the digital processing engine 804 outside of the IC 801. If using this device to determine if a chip is counterfeit or genuine, the final decision would be made by another device that is communicating to the IC 801. The digital processing engine 804 may simply provide samples to an outside assessment system, which performs the comparison of current measurements on this device with a known genuine device.

Depending on the level of integration, the on-chip section may only include portions of the complete test apparatus. One embodiment may only include the current measurement 802 on the IC 801, requiring an external apparatus to provide the analog processing circuitry, analog-to-digital converter, and digital processing block.

FIG. 9 shows additional details of an embodiment designed for performing an in-circuit test. In this embodiment the device under test (DUT) 900 is a microcontroller, where said DUT 900 is capable of adjusting its own operating frequency. The digital processing engine 901 reprograms the DUT 900 with the software 903 to execute during generation of the power signature. The reprogramming interface is shown as interconnection 902 between the DUT 900 and digital processing engine 901. This interface 902 may be reused for communication of test parameters and results as well.

The DUT 900 has an external oscillator 904, which is used by the Phase Lock Loop (PLL) 905 to generate the operating frequency of the processor core 906. It may be desired for the digital processing engine 901 to know the target device clock phase for generating power samples with known and/or constant temporal alignment, in which case connection 907 provides information about the clock phase.

The power samples themselves are taken with a sensor 908 (such as a resistor inserted into the power line), analog processing circuitry 909 (such as but not limited to a differential amplifier), and the analog-to-digital converter (ADC) 910. The ADC 910 is connected to the digital processing engine 901 to transfer data and clock information using a plurality of interconnections 911.

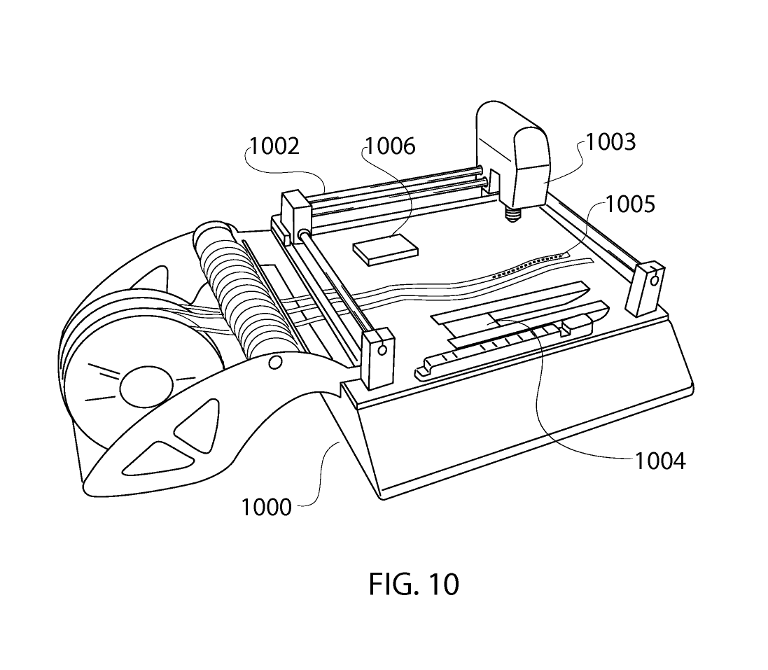

It may be desired to test a device immediately before placing the part of a printed circuit board. This may require a modification of the apparatus to allow use with automated assembly equipment such as pick and place machines. This is shown in FIG. 10, where the apparatus is configured to automatically test an integrated circuit as part of the assembly process.

Testing apparatus embodying the principles of this invention can be seen as an addition to the standard pick and place machine 1000 widely used in automated assembly. Said pick and place machine has a pick head 1003, which is capable of picking up electronic components 1005. These components can include a wide arrange of devices such as integrated circuits, resistors, capacitors, and transistors. The pick head 1003 is capable of using arms 1002 to precisely locate the component 1005 on the circuit board 1004. The component can then be released onto the circuit board 1004.

An additional test apparatus 1006 has been added, which is similar to the stand-alone apparatus described in FIG. 5 and FIG. 6. This apparatus is configured to allow the pick head 1003 to place the component in the test apparatus 1006. The apparatus determines if the component is genuine, and if so sends a command to the pick and place machine 1000 to continue. The pick head 1003 then removes the component from the test apparatus 1006 and places the component on the circuit board 1004.

Integrating the test apparatus 1006 into the assembly cycle performed by the pick and place machine 1000, reduces the possibility of a fraudulent device being introduced to a circuit board assembly. The test apparatus 1006 may need to support special features to allow the pick head 1003 to place and remove parts into the test apparatus 1006. This could also require the test apparatus 1006 to support multiple component footprints: for example, Ball-Grid Array (BGA), Small Outline Integrated Circuit (SOIC), and Quad Flat Pack (QFP) packages all have different component outlines and lead spacings. This may require the apparatus to have separate connection modules for each possible component being tested.

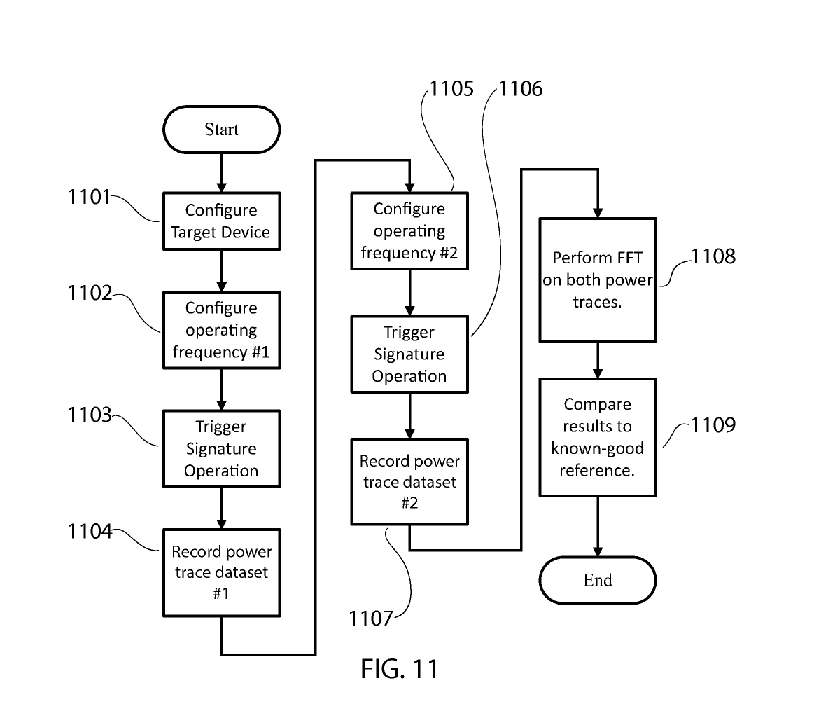

The test apparatus involves a programmable digital processing engine, which runs the test algorithm. A flow chart of the algorithm (such as running in software on the digital processing engine 101) is given in FIG. 11.

The algorithm begins at step 1101 by configuring the target device under test (DUT). When testing a programmable target this could entail loading the special test program into said DUT, this test program performing operations such as configuring peripherals or exercising certain features of said DUT.

The test apparatus then configures the first set of environmental conditions. This is shown at step 1102 as configuring the operating frequency of the DUT. If using different operating voltages instead of, or in addition to, multiple operating frequencies, this step could also entail configuration of a programmable power supply. If the DUT is generating a clock internally, the operating frequency configuration can be done by code on the DUT itself.

The test apparatus then triggers the reference signature operation on the DUT at step 1103. The specifics of triggering this operation will vary for different DUT. If testing a programmable processor, this could entail requesting the processor perform the sequence of operations programmed in at step 1101. If testing an application-specific DUT, this could entail using external signals to cause some known operation to be performed by said DUT.

The signature operation can also involve inputting of known analog signals to the DUT. If testing an analog-to-digital converter (ADC), the test operation may involve having the ADC digitize a known signal at a specific sample rate. The specific signals are highly dependent on the device being tested (the “target” or “DUT”), and those skilled in the art can appreciate the multitude of possible methods of causing some known operation to occur on various devices.

The test apparatus records a dataset containing the power consumption of the DUT at step 1104. The power traces will encompass the timeframe under which the DUT is performing the signature operation from step 1103. The DUT may be configured to output a trigger signal at the critical moment the signature operation is being performed in order to assist the test apparatus with recording the power traces.

Steps 1105, 1106, and 1107 of the algorithm perform the same operations as steps 1102, 1103, and 1104 of the algorithm but under different operating conditions. In this example step 1105 configures the DUT for a different (lower or higher) operating frequency than was used in step 1102. Once again the signature operation is triggered at step 1106, and power dataset is recorded at step 1107.

The recorded power trace dataset from steps 1104 and 1107 are then compared to a known-good reference dataset in steps 1108 and 1109. There are many options for the processing performed on these power traces and the method used to compare the known-good reference.

In this example a Fast Fourier Transform (FFT) is used at step 1108 to determine the signature in the frequency domain. This provides information about the magnitude of each frequency component during the tests run under different environmental conditions.

Various other algorithms can be used to determine important features in the power traces recorded at steps 1104 and 1107. Examples include using principal component analysis (PCA) to determine principal components in the various waveforms, instead of using the FFT to only determine distinctive frequencies.

The comparison at step 1109 also has many variations. A simple test may use high and low limits for each possible frequency component to determine a genuine device, as shown in FIG. 4 and described earlier. The output of step 1109 designates the DUT as being a counterfeit or damaged exemplar of the particular device design. This can then be presented to a user for manual action, or be used as part of further automated processing, such as rejecting the suspect part.

While exemplary embodiments of the present invention have been described with respect to standard digital and analog blocks, as would be apparent to one skilled in the art, various functions may be implemented in the digital domain as processing steps in a software program, in hardware by circuit elements or state machines, or in combinations of both software and hardware. Such software may be employed in, for example, a digital signal processor, microcontroller, or general-purpose computer. Such hardware and software may be embodied within circuits implemented within an integrated circuit.

Thus, the functions of the present invention can be embodied in the form of methods and apparatuses for practicing those methods. One or more aspects of the present invention can be embodied in the form of program code, for example, whether stored in a storage medium, loaded into and/or executed by a machine, or transmitted over some transmission medium, wherein, when the program code is loaded into and executed by a machine, such as a computer, the machine becomes an apparatus for practicing the invention. When implemented on a general-purpose processor, the program code segments combine with the processor to provide a device that operates analogously to specific circuits.

It is to be understood that the embodiments and variations shown and described herein are merely illustrative of the principles of this invention and that various modifications may be implemented by those skilled in the art without departing from the scope and spirit of the invention.

What is claimed is:

1. Apparatus for determining if a device under test (DUT) is, or includes, a counterfeit, damaged or defective device, the apparatus including a computer-readable medium on which are stored program instructions that, when executed by one or more processors,
configure the DUT to perform a signature operation under at least a first environmental condition;
generate a first dataset indicative of at least a first signature of the DUT during the performance of the signature operation under the at least first environmental condition;
configure the DUT to perform the signature operation under at least a second environmental condition;
generating a second dataset indicative of at least a second signature of the DUT during the performance of the signature operation under the at least second environmental condition;
compare the first and second datasets to first and second reference datasets, respectively, the first and second reference datasets being indicative of the signature of a known-good device performing the signature operation under the at least first and second environmental conditions, respectively; and
generate a signal designating the DUT as being potentially defective or counterfeit in response to there being predetermined differences between at least one of a) the first dataset and the first reference dataset and b) the second dataset and the second reference dataset.

2. The apparatus of claim 1 wherein the first and second datasets are samples of the at least first signature generated at a sample rate that is sufficient to ensure that said predetermined differences are detectable.

3. The apparatus of claim 1 wherein the signature operation includes at least one of a) executing at least one instruction, b) performing at least one operation, or c) configuring at least one logic element.

4. The apparatus of claim 1 wherein the at least first and second signatures are each one of a) power consumption of DUT and b) electromagnetic energy emitted by the DUT.

5. The apparatus of claim 1 wherein the first and second environmental conditions respectively include at least one of a) first and second operating clock frequencies of the DUT, and b) first and second operating voltages of the DUT.

6. The apparatus of claim 1 wherein the apparatus is configured to allow temporary connection of the DUT to the apparatus using one or more temporary probes.

7. The apparatus of claim 1 wherein the apparatus is an integral and permanent part of the DUT.

8. A method comprising causing a device under test (DUT) to carry out a known task, operation or function under at least a first operating condition of the DUT;
recording a first sequence of samples of a particular measurement that is a function of at least one of a) power consumption of the DUT and b) electromagnetic energy radiated from the DUT during the time that the DUT is performing the known task, operation or function under the at least first operating condition of the DUT;
causing the DUT to carry out the known task, operation or function under at least a second operating condition of the DUT;
recording a second sequence of samples of the particular measurement during the time that the DUT is performing the known task, operation or function under the at least second operating condition of the DUT;
concluding that the DUT is at least one of a) defective or b) counterfeit, in response to the occurrence of at least one of the following:
i) the first sequence of samples is different in a predetermined way from a sequence of samples of the particular measurement taken during a time that a known-good device was performing the known task, operation or function under the at least first operating condition of the DUT;
ii) the second sequence of samples is different in a predetermined way from a sequence of samples of the particular measurement taken during a time that said known-good device or another known-good device was performing the known task, operation or function under the at least second operating condition of the DUT, wherein each said known-good device has a same particular device design as the DUT.

9. The method of claim 8 wherein the known operation or function includes at least one of a) executing at least one instruction, b) performing at least one operation, or c) configuring at least one logic element.

10. The method of claim 8 wherein the first and second operating conditions respectively include at least one of a) first and second operating clock frequencies of the DUT, and b) first and second operating voltages of the DUT.

11. A method comprising determining, when at least one of two criteria are met, that a device under test (DUT) is a defective, counterfeit or damaged exemplar of a device having a particular device design,
wherein the first criterion is that a first version of a signature signal resulting from operation of the DUT when performing at least a first signature operation under at least a first environmental condition differs in a particular way from a second version of the signature signal that had resulted from operation of a reference device having the particular device design when performing the at least first signature operation under the at least first environmental condition,
and wherein the second criterion is that a third version of the signature signal resulting from operation of the DUT when performing at least the first signature operation under at least a second environmental condition differs in a particular way from a fourth version of the signature signal that had resulted from operation of the reference device when performing the at least a first signature operation under the at least second environmental condition.

12. The method of claim 11 wherein the first and second environmental conditions are different device operating voltages.

13. The method of claim 11 wherein the first and second environmental conditions are different device operating frequencies.

14. The method of claim 11 wherein the first, second, third and fourth versions of the signature signal are each indicative of at least one of a) device power consumption, or b) device-emitted electromagnetic energy.

15. The apparatus of claim 11 wherein the signature operation includes at least one of a) executing at least one instruction, b) performing at least one operation, or c) configuring at least one logic element.

16. An apparatus for determining that a device under test (DUT) is a counterfeit, defective or damaged exemplar of a particular device design, the apparatus including a digital processing engine configured to command the DUT to perform a signature operation under at least two different environmental conditions of the DUT;
compare test signatures of the DUT resulting from the signature operation under the at least two different environmental conditions of the DUT to respective reference signatures of at least one known-good exemplar of the particular device design that had performed the signature operation under the at least two different environmental conditions, and
designate the DUT as potentially being a counterfeit or damaged exemplar of the particular device design when either one or both of the test signatures differs in a predetermined way from its respective reference signature.

17. The apparatus of claim 16 wherein the test signatures are sampled signals generated at a sample rate that is sufficient to enable differences in said predetermined way between one or both of the test signatures and their respective reference signatures to be discernible.

18. The apparatus of claim 16 wherein the signature operation includes at least one of a) executing at least one instruction, b) performing at least one operation, or c) configuring at least one logic element.

19. The apparatus of claim 16 wherein each of the test signatures is a signal indicative of one of a) power consumption of DUT and b) electromagnetic energy emitted by the DUT.

20. The apparatus of claim 16 wherein the two environmental conditions include at least one of a) first and second operating clock frequencies of the DUT, and b) first and second operating voltages of the DUT.

21. The apparatus of claim 16 wherein the digital processing engine is configured to allow connection of the DUT to the apparatus using temporary probes.

22. The apparatus of claim 16 wherein the digital processing engine is an integral and permanent part of the DUT.
